(19) United States
(12) Patent Application Publication
(10) Pub. No.: US 2021/0055331 A1
(43) Pub. Date: Feb. 25, 2021

(54) Method and Apparatus for Securing a Watthour Meter Box

(71) Applicant: DeWalch Technologies, Inc., Houston, TX (US)

(72) Inventor: John Edward Stachowiak, Jr., Houston, TX (US)

(73) Assignee: DeWalch Technologies, Inc., Houston, TX (US)

(21) Appl. No.: 16/917,767

(22) Filed: Jun. 30, 2020

Related U.S. Application Data
(63) Continuation of application No. 12/317,086, filed on Dec. 20, 2008.
Application No. 12/317,086 is a continuation of application No. 11/434,665, filed on May 16, 2006, now abandoned.
(60) Provisional application No. 60/793,104, filed on Apr. 19, 2006.
(60) Provisional application No. 60/681,200, filed on May 16, 2005.

(51) Int. Cl. G01R 11/24; F16B 21/16; G01R 11/04; F16B 41/00; H02B 1/03; H02B 1/06; H05K 5/02

(52) U.S. Cl. CPC G01R 11/24; Y10T 70/5558; G01R 11/04; F16B 41/005; H02B 1/03; H02B 1/063; H05K 5/0208; H05K 5/0221; Y10T 29/49947; Y10T 29/49826; Y10T 70/5566; Y10T 292/1043; Y10T 292/1052; Y10T 292/1059; F16B 21/165

(57) ABSTRACT

A locking bracket and a lock housing wherein the locking bracket generally comprises a clamping member and a fastening lever that attaches to a wall of a meter box base. The lock housing generally comprises a unitary member with a perpendicular flange. The meter box lid is secured to the meter box base when the locking bracket is secured to the side wall and used in combination with the lock housing and a locking shaft.

This application is a continuation of application Ser. No. 12/317,086, filed on Dec. 20, 2008, which is a continuation of application Ser. No. 11/434,665, filed on May 16, 2006, which claims the benefit of U.S. Provisional Patent Applications No. 60/681,200, filed May 16, 2005, and No. 60/793,104, filed Apr. 19, 2006.

All written material, figures, content and other disclosure in each of the above-referenced applications is hereby incorporated by reference.

### BACKGROUND OF THE INVENTION

### 1. Field of the Invention

The present invention relates generally to locking structures, and more specifically, it relates to a locking structure for securing the lid of a utility service enclosure such as, for example, a watthour meter box.

### 2. Description of the Background

Electrical service providers generally deliver electricity to their customers via power lines buried underground or distributed along poles or towers overhead. The provider's power lines are usually distributed from a power generation station to numerous sets of customer lines, so that customers can then use the power to satisfy their various electrical needs. To measure delivered power so that customers can be billed in proportion to their usage, service providers typically terminate their power lines at a customer's home or business facility through a metered socket box, various designs for which are well known.

A meter box is generally used by electric utility companies, however the invention herein may be used with other utility service enclosures in the gas, water, cable, TV utility industries or in other industries as well.

An example of one previously known meter box consists of two sets of electrical posts, with a provider's transmission lines being connected to one set of posts, and the customer's service lines to the other set. In order to measure the amount of electricity a customer uses, the meter box is configured to accept a watthour meter or another electricity usage measurement device which, when plugged into the socket box, permits transmission of electricity from the provider to the customer and allows the amount of transmitted electricity to be accurately measured, so that the provider can charge the customer for power usage at an appropriate rate.

Various designs and uses for watthour meters are also well known, and all such designs and uses are incorporated by reference into the teachings of the present invention. The present invention is also applicable in situations where the customer's service lines are routed from the meter box to a breaker box so that electricity can be distributed to multiple service locations using additional sets of electrical lines or wires.

Presently, there are two common types of meter socket boxes, each distinguished by the manner in which the meter is secured in place once it has been plugged into an electrical socket disposed in the meter box. For example, a ringed type meter box fitted with a flanged front cover is known, within which a watthour meter is disposed so that a head portion of the meter passes out through a flanged opening in the front cover. In this configuration, the meter is generally held in place using an annular, lockable sealing ring.

Also known is a ringless type meter box, in which the box cover secures the meter in place. For example, a ringless type meter box may include a box cover and a box base. Formed around an opening in a central portion of meter box cover is a flange. A complementary flange is disposed on the meter such that when meter box cover is installed over and around the head of meter, then the meter complementary flange is encased by meter box cover flange, so that the meter cannot be easily removed from the electrical socket unless the cover is first removed from the meter box base.

The meter box cover is typically secured in place by means of a small latch assembly, which functions in structural cooperation with a complementary latch-receiving member disposed on the meter box base. The meter box cover is used to secure the meter to the electrical socket (not shown), so that completion of an electrical circuit is ensured, and the meter is reliably prevented from falling out of the meter box socket.

The meter box cover also prevents unauthorized persons from tampering with the meter. For example, some customers have attempted to bypass the meter, so that unmeasured electricity could be used free of charge. Also, service providers are sometimes forced to disconnect service to customers, for example, due to non-payment of monthly bills. In this event, a locked meter box cover helps prevent a customer from entering the meter box and reconnecting electrical service. However, in instances where the small latch assembly on the meter box fails to provide sufficient security for preventing unauthorized access to the meter and meter box socket, a sturdier, more tamper resistant solution is required.

There are presently only a few commonly used security devices for securing meter box covers to socket boxes. One type requires an installer to drill or punch a hole in the meter box prior to installation of a fastening device. However, some installers are independent contractors rather than employees of the companies that own the meter boxes, and thus drilling or punching a starter hole in the box is sometimes undesirable. Also, drilling takes additional time and adds more steps to the installation, each of which could be avoided if drilling were not required.

To overcome these shortcomings, there are also locks that can be installed on ringless meter socket boxes that do not require drilling or punching a hole in the meter box. Several examples of patents which disclose attempts to solve some of the above problems are set forth as follows.

The Inner-Tite Jiffy Lock™ or “IT Lock,” shown in U.S. Patent No. D-463,248, and U.S. Pat. No. 6,763,691 to Rafferty, entitled “Meter Box Lock Assembly,” is directed to lock assembly for use in combination with an electric meter box or other like enclosure having a bottom, a side wall, and a cover which may be opened to gain access to the interior of the box, and which when closed, overlaps an upper edge of the side wall. The lock assembly includes a bracket having first and second mutually spaced flanges integrally joined by an intermediate web. A jaw is mechanically interengaged with and carried by the bracket for movement between its flanges. The bracket is configured for removable mounting on the side wall, with its intermediate web interposed between the cover and the upper edge of the side wall, and with the first flange and the jaw respectively located adjacent exterior and interior surfaces of the side wall. The jaw is urged towards the first flange to clamp the side wall therebetween, and a cap is secured to the bracket. The cap has a lip configured and dimensioned to overlap and maintain the cover in a closed position.

The McGard Intimidator Sidewinder-Lock™ shown in U.S. Pat. No. 6,742,365 to Sullivan et al, entitled “Ringless Meter Lock,” sets forth a locking mechanism for securing the cover of a thin-walled box to the box frame. The locking mechanism includes a clip bracket adapted to engage a wall of the box frame, a lock body adapted to latch to the clip bracket and engage the box cover, a locking member carried by the clip bracket and adapted to clamp the clip bracket to the box wall when the locking member is in a clamping position, and a pivotable actuating lever adapted to actuate the locking member into the clamping position. The locking member and the actuating lever can be implemented as a two-piece system comprising first and second pivoting members. Alternatively, the locking member and the actuating lever can be integrally formed as a one-piece system. The locking mechanism is capable of multiple mounting positions on the box without drilling, and uses a spring-loaded plunger assembly that allows for quick, keyless, slam installation.

There remains a need for a meter box security device that can be easily and quickly installed, which reliably ensures that the box cover cannot be shut once the support assembly is hung on a wall, unless the clamping member is properly secured to a meter box wall. There is also a need for a meter box security apparatus that offers greater security for preventing unauthorized entry into a meter box than is known in the prior art. There is also a need for a meter box security device having a reduced number of parts, so as to limit system complexity and hold down manufacturing costs.

Those of skill in the art will appreciate the present invention which addresses the above needs and other significant needs the solution to which are discussed hereinafter.

### SUMMARY OF THE INVENTION

An object of the present invention is to provide additional security to a watthour meter box.

Another object of the present invention is to secure the watthour meter box lid to the meter box base

Another object of the present invention is to provide a watthour meter box security apparatus that helps prevent unauthorized watthour meter box lid removal from the watthour meter box base

Another object of the present invention is to provide a watthour meter box security apparatus that can be installed without any tools.

Another object of the present invention is to provide a watthour meter box security apparatus that can be attached to the wall of watthour meter box base.

Another object of the present invention is to provide a watthour meter box security apparatus that will not interfere with dangerous components inside the meter box.

Another object of the present invention is to provide a watthour meter security apparatus that will not interfere with the normal operation of the lid.

These and other objects, features, and advantages of the present invention will become apparent from the drawings, the descriptions given herein, and the appended claims. However, it will be understood that the above-listed objectives and/or advantages of the invention are intended only as an aid in quickly understanding aspects of the invention, are not intended to limit the invention in any way, and therefore do not form a comprehensive or restrictive list of objectives, and/or features, and/or advantages. Accordingly the present invention provides an apparatus for securing a box cover to a watthour meter socket box so as to address the needs as described above.

The general purpose of the present invention, which will be described subsequently in greater detail, is to secure the lid of a watthour meter box to the base of a watthour meter box.

One example embodiment of the present invention includes at least a locking bracket and a lock housing. The locking bracket includes at least a clamping member, fastening lever, and compression member. In an alternative embodiment, the locking to bracket further includes at least a flexural member.

The lock housing generally includes at least a lock body or member incorporating a flange. The flange preferably has a generally perpendicular orientation with respect the lock housing. In one example embodiment, the lock housing has a unitary configuration. The locking bracket is adapted to be attached to a portion of a wall of the watthour meter box and to receive the lock housing after the lid of the watthour meter box is in place.

An example embodiment includes at least a shaft-style locking device cooperatively configured for securing the lock housing to the locking bracket so as to prevent removal of the meter box lid from the meter box base. In an alternative embodiment, the lock housing may be configured for use with any locking device suitable for securing the lock housing to the locking bracket so as to prevent removal of the meter box lid.

In an alternate embodiment, a locking device for securing the lid of a watthour meter box to a watthour meter box base includes at least: a latch assembly and a lock housing member, said latch assembly adapted to affix to a wall of a watthour meter box base, said latch assembly comprising a bracket member and a lever member, a first bracket portion disposed on said bracket member adapted to pivotably carry said lever member allowing rotational motion of said lever member about an axis located generally perpendicular to the planar face of said first bracket portion, a portion of said lever member adapted to bear against a wall of said meter box base thus trapping said wall between a second bracket portion disposed on said bracket member, a third bracket portion disposed on said bracket member adapted to be received by and affixed to said lock housing member, a flange disposed on said lock housing member adapted to secure a meter box lid to a meter box base.

In one example embodiment, a method for securing a lid to a watthour meter box having an interior is provided. The method includes at least: attaching a locking bracket to a wall of the watthour meter box; installing the lid over at least a portion of the bracket; and securing a locking housing to the bracket to prevent removal of the lid. In one example embodiment, the step of attaching the locking bracket to the wall of the watthour meter box is performed from a position substantially outside the interior of the watthour meter box. In this way, the bracket is substantially manipulable without needing to place any portion of one's hand or an object in the interior of the watthour meter box.

In another example embodiment, attaching means may be used for mounting the bracket to the wall of the watthour meter box without having to reach into the interior of the box. A latch member may be lever-type structure and a member engageable with a meter box wall. Various locking means may be used to secure the lid to the watthour meter box.

In another example embodiment the locking bracket includes at least a body and only one moveable member. In another embodiment, the moveable member is pivotable with respect to the body. In another embodiment, the moveable member preferably further includes at least a compression member.

In an example embodiment, the moveable member includes at least an actuating lever which is moveable (or for example, pivotable) in a plane that is substantially parallel to the plane of the wall to which the locking bracket is being attached. The actuating lever ideally is configured with a compression member at a distal end of the actuating lever such that the compression makes arcuate (or sweeping rotational) engagement with the wall when force is applied to the actuating lever. The actuating lever is ideally configured with at least one elongated member which serves as a moment arm to facilitate engagement.

In another example embodiment, the locking bracket includes at least a reversible design configuration. That is, the locking bracket may be manufactured in a first design configuration such that the actuating lever may be rotated in a functional clockwise direction to attach the bracket or in a second design configuration such that the actuating lever may be rotated in a functional counter-clockwise direction to attach the bracket. The first or second design configuration may be employed as desired for use in situations where there are limited locations for attaching the locking bracket or to foster ease of use by a right- or left-handed person.

Another example embodiment of the present invention includes at least a locking bracket for use with a lock housing. The locking bracket includes at least a clamping member, fastening lever, and compression member. The locking bracket is configured for mounting a lock housing to capture at least a portion of the lid of a watthour meter box. A locking shaft is adapted to be installed in the lock housing so as to secure the lid in place on the watthour meter box.

In another example embodiment of the apparatus the lever end is in functional cooperation with a portion of a lock housing mounted to a portion of the clamping member such that the lock prevents rotation of the lever to an open position.

In another example embodiment of the apparatus the lever end is in functional cooperation with a portion of a meter box lid such that the lid prevents rotation of the lever to an open position.

In another example embodiment of the apparatus the lever end is at least partially outside the interior of the meter box in a mounting position and at least partially inside the interior of the meter box in a locked position.

In another example embodiment of the apparatus further comprises the meter box.

In another example embodiment of the apparatus further comprises a locking structure adapted for functional cooperation with said clamping member for securing a meter box lid to a meter box base.

The content and disclosure of each of the following applications/publications are specifically hereby incorporated by reference: application Ser. No. 12/317,086, filed on Dec. 20, 2008; application Ser. No. 11/434,665, filed on May 16, 2006; U.S. Provisional Patent Applications No. 60/681,200, filed May 16, 2005, and No. 60/793,104, filed Apr. 19, 2006.

There has thus been outlined, rather broadly, the more important features of the invention in order that the detailed description thereof may be better understood, and in order that the present contribution to the art may be better appreciated. There are additional features of the invention that will be described hereinafter.

In this respect, before explaining at least one example embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of the description and should not be regarded as limiting.

To the accomplishment of the above and related objects, this invention may be embodied in the form illustrated in the accompanying drawings, attention being called to the fact, however, that the drawings are illustrative only, and that changes may be made in the specific construction illustrated.

### BRIEF DESCRIPTION OF THE DRAWINGS

Various other objects, features and attendant advantages of the present invention will become fully appreciated as the same becomes better understood when considered in conjunction with the accompanying drawings, in which like reference characters designate the same or similar parts throughout the several views, and wherein:

FIG. 1 is a perspective view of the present invention installed onto the watthour meter box in accord with one possible embodiment of the present invention.

FIG. 2 is a side-section view of the present invention installed on a meter box viewed from inside the box in accord with one possible embodiment of the present invention.

FIG. 2A is a side-section view of the present invention as shown in FIG. 2 which may or may not utilize biasing means and wherein if used, the biasing means may or may not replace, or be used in conjunction with, a flexural member in accord with another possible embodiment of the present invention.

FIG. 3 is a side view of the present invention installed on a meter box viewed from inside the box showing the various components of the locking apparatus.

FIG. 3A is a side-section view of the present invention as shown in FIG. 3 which may or may not utilize biasing means and wherein, if used, the biasing means may or may not replace, or be used in conjunction with, a flexural member in accord with another possible embodiment of the present invention.

FIG. 4 is a perspective view of the present invention viewed generally from below, showing the various components of the locking bracket.

FIG. 4A is a side-section view of the present invention as shown in FIG. 4 which may or may not utilize biasing means and wherein, if used, the biasing means may or may not replace, or be used in conjunction with, a flexural member in accord with another possible embodiment of the present invention.

FIG. 5 is a perspective-exploded view of the present invention showing the various components of the locking bracket FIG. 5A is a side-section view of the present invention as shown in FIG. 5 which may or may not utilize biasing means such as a compression member and wherein, if used, the biasing means may or may not replace, or be used in conjunction with, a flexural member in accord with another possible embodiment of the present invention.

FIG. 6 is a perspective view of the present invention, illustrating the installation of the entire apparatus onto the meter box base.

FIG. 6A is a side-section view of the present invention as shown in FIG. 6 which may or may not utilize biasing means such as a compression member and wherein, if used, the biasing means may or may not replace, or be used in conjunction with, a flexural member in accord with another possible embodiment of the present invention.

FIG. 7 is a perspective view of the present invention, viewed from below the meter box base front flange, illustrating the installation of the locking bracket onto the meter box base. Portions of the meter box base have been cut away.

FIG. 7A is a side-section view of the present invention as shown in FIG. 7 which may or may not utilize biasing means such as a compression member and wherein, if used, the biasing means may or may not replace, or be used in conjunction with, a flexural member in accord with another possible embodiment of the present invention.

FIG. 8 is a perspective view of the present invention, illustrating the locking apparatus position after installation, viewed from below. Portions of the meter box base and lid have been cut away.

FIG. 9 is a perspective view of the present invention illustrating the lock housing position after apparatus installation. Portions of the meter box base and lid have been cut away.

FIG. 10 is a perspective view of an alternate embodiment of the present invention showing the various components of the locking bracket in the “closed” position.

FIG. 11 is a perspective view of an alternate embodiment of the present invention showing the various components of the locking bracket in the “closed” position.

FIG. 12 is a perspective view of an alternate embodiment of the present invention showing the various components of the locking bracket in the “open” position.

FIG. 13 is a perspective view of another alternate embodiment of the present invention showing the various components of the locking bracket in the “closed” position.

While the present invention will be described in connection with presently preferred embodiments, it will be understood that it is not intended to limit the invention to those embodiments. On the contrary, it is intended to cover all alternatives, modifications, and equivalents included within the spirit of the invention and as defined in the appended claims.

### DESCRIPTION OF PRESENTLY PREFERRED EMBODIMENTS

Turning now descriptively to the drawings, in which similar reference characters denote similar elements throughout the several views, the attached figures illustrate an apparatus for securing a watthour meter box.

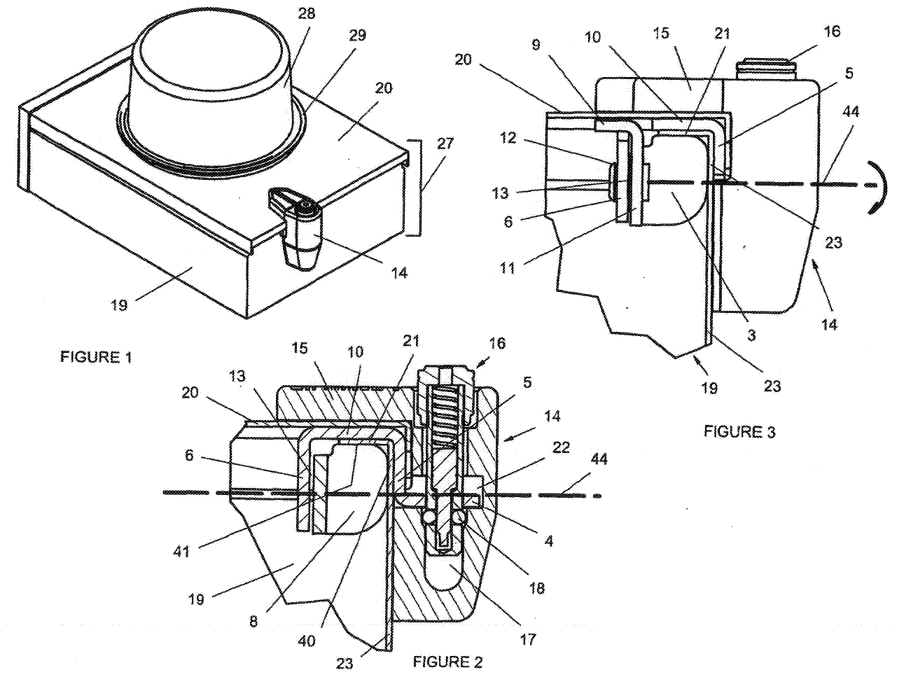

Referring now to FIG. 1, there is shown a ringless type meter box 27 that includes a box cover 20, and a box base 19. Formed around an opening in a central portion of meter box cover 20 is a flange 29. A complementary flange is disposed on meter 28 such that, when meter box cover 20 is installed over and around the head of meter 28, the meter complementary flange is encased by meter box cover flange 29, so that the meter cannot be easily removed from the electrical socket unless the cover 20 is first removed from the meter box base 19.

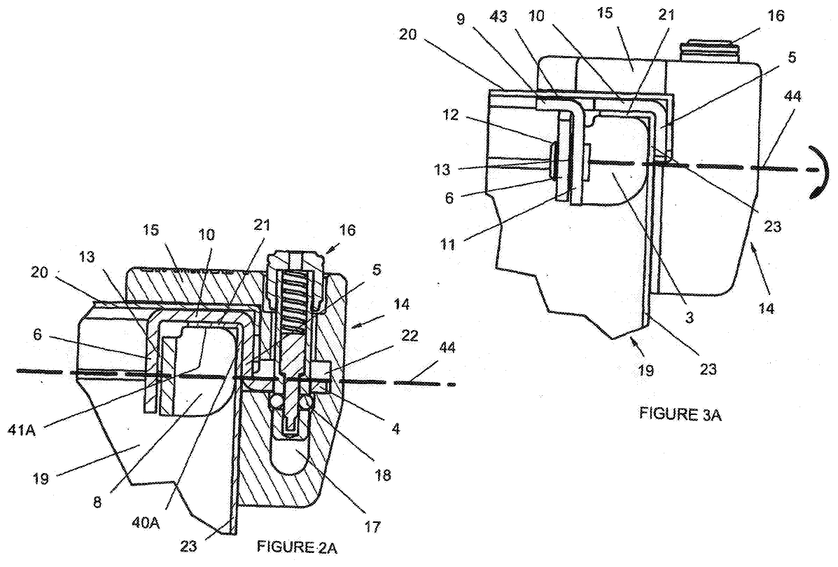

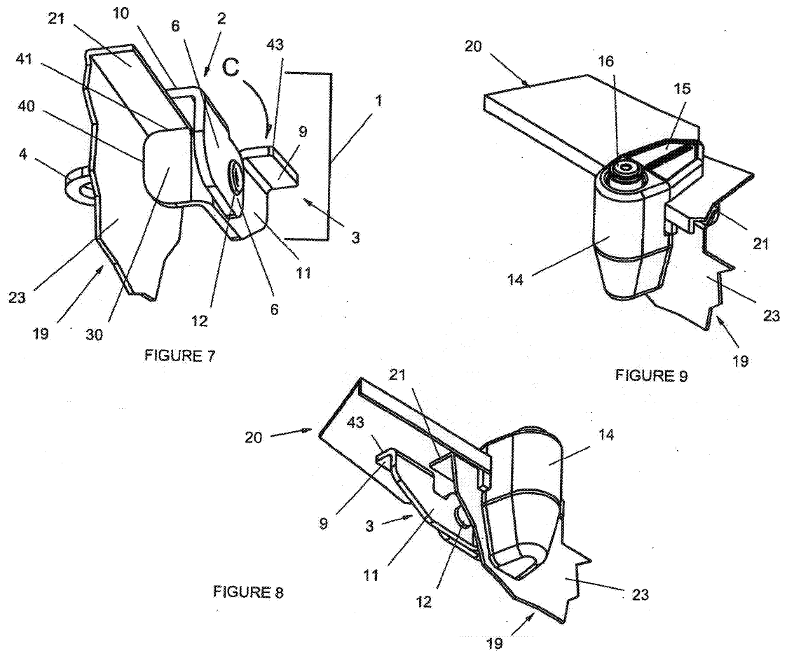

The meter box cover 20 is typically secured in place by means of a small latch assembly, which functions in structural cooperation with a complementary latch-receiving member disposed on the meter box base 19. The meter box cover 20 is used to secure the meter 28 to the electrical socket (not shown), so that completion of an electrical circuit is ensured, and the meter is reliably prevented from falling out of the meter box socket. The meter box cover 20 also prevents unauthorized persons from tampering with the meter 28. As shown in FIGS. 2 and 7, meter box base 19 comprises wall 23. Wall 23 comprises front flange 21 which extends inwardly from wall 23.

Referring now to FIGS. 1, 2, 2A, 3, and 3A, there is shown watthour meter box 27 wherein lock housing 14 may be utilized for securing meter box cover 20 to meter box base 19. The lock housing 14 is generally comprised of a unitary member incorporating a generally perpendicular flange 15 and multiple apertures or openings which may be interconnected such as 17, 22. Opening 17 may extend into lock housing perpendicular to perpendicular flange 15 and extend through opening or aperture 22, which may, if desired, be generally transverse to opening 17. Aperture 22 preferably opens onto an interior side of lock housing 14 and receives fastening shelf 4 of clamping member 2. As shown in FIGS. 2 and 2A, lock housing 14 may be used in conjunction with clamping member 2 such that cover 20 is held in place between flange 10 of clamping member 2 and perpendicular flange 15 of lock housing 14.

The clamping member 2 is generally comprised of multiple flanges 6, 10, 5 with one of the flanges 6 containing a preferably circular aperture 24 and a fastening shelf 4 that also contains a preferably circular aperture 7. Additional flanges may be added or fewer flanges may be used to accomplish the function as described henceforth.

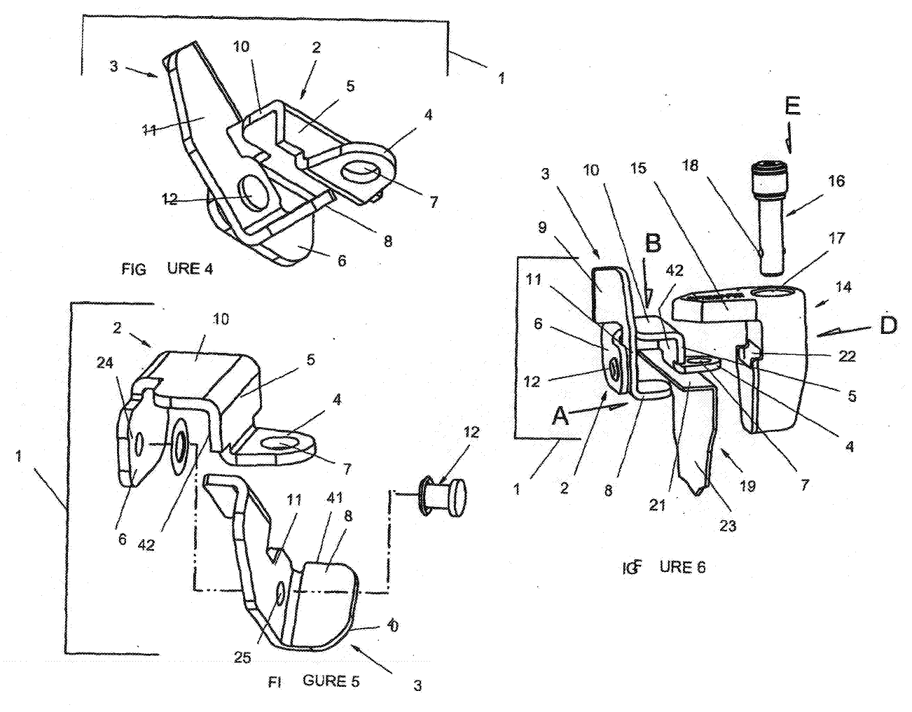

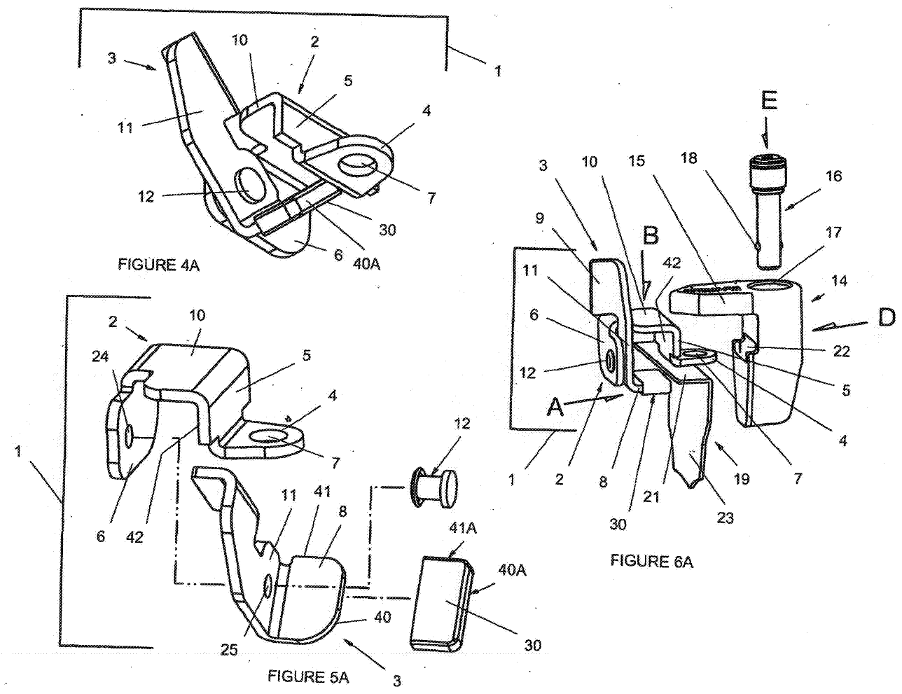

A locking bracket 1 as shown enlarged in FIGS. 4, 4A, 5, 5A6, and 6A may generally comprise clamping member 2 and a fastening lever 3. The fastening lever 3 is generally comprised of multiple flanges 8, 9, 11 with one of the flanges 11 containing a generally circular aperture 25. Additional flanges may be added or fewer flanges may be used to accomplish the function as described henceforth.

As shown in the exploded view of the embodiment of FIG. 5, the fastening lever 3, flexural member 13, and clamping member 2 may be joined through the corresponding apertures 25, 24 with a permanent type fastener 12, which may be a rivet or other type of fastener which allows rotational motion between fastening lever 3, and clamping member 2. Fastener 12 is preferably permanent (but may also be non-permanent and easily removable). Flexural member 13 is partially compressed between the flanges 6 and 11 of clamping member 2 and fastening lever 3. The flexural member is a compressible member which applies a biasing force that biases clamping member 2 and fastening lever 3 away from each other or to separate.

In the embodiment of FIG. 5A, a compression member 30 is adapted to be received by a flange 8 disposed on fastening lever 3. Compression member 30 may be attached to flange 8 by various means, one of which is shown and may comprise a cap. Flange 8 comprises edge 40 and stop surface 41 such that once compression member 30 is installed, comprise terminate edge 40A and stop surface 41A. It will be appreciated that edge 40 or terminate edge 40A is a surface although preferably narrow in width and rotates and engages the wall 23 at the same time. Compression member 30 may be wholly or partially comprised of elastomeric material, plastic, or other compressible material. The compressible material may preferably also be resilient so as to permit repeated reuse. The compressible material is also preferably an electrical insulator which reduces any likelihood of contacting electricity which might possibly be present within meter box base 19. Compression member 30 may be used in place of flexural member 13, or in conjunction with it, or with other compression members.

The directly subsequent discussion of assembly and operation of locking bracket 1 onto base 19 of watthour meter box 27 is made using the example of compression member 30, but resilient compression members such as flexural member 13, or other resilient compression members discussed hereinafter, or compression members such as lobe 34 which may or may not be resilient, may be utilized to provide a secure fit of locking bracket 1 onto base 19. Compression members may be used with or without each other.

Referring to FIG. 6A, the locking bracket 1 is installed onto the base 19 of the watthour meter box 27 in the following manner: The fastening lever 3 is first rotated to an “open” position as shown with the flange 9 of the fastening lever 3 in a generally perpendicular position to the flange 10 of the clamping member 2. The locking bracket is moved toward the wall 23 of the meter box base 19, shown by movement arrow “A”, allowing the front flange 21 of the meter box base 19 to pass between the compression member 30 disposed on flange 8 of the fastening lever 3 and the fastening shelf 4 of the clamping member 2. The locking bracket 1 is then lowered onto the front flange 21 of the watthour meter box base 19 shown by movement arrow “B” until the front flange 21 of the meter box base 19 is in contact with the flange 10 of the clamping member 2.

Now referring to FIG. 7A, which shows a view on the other side of that shown in FIG. 6A, the installer bears on flange 9 of the fastening lever 3 causing the fastening lever 3 to rotate to a “closed position”, shown by movement arrow “C”. As shown in FIG. 3A, it will be seen that rotation of fastening lever 3 is around axis of rotation 44, which may be generally transverse, perpendicular, or orthogonal to wall 23. In this embodiment, axis of rotation 44 is orthogonal to wall 23, parallel to box cover 20, perpendicular to flange 5, and parallel to a plane of fastening shelf 4. In this embodiment, rotation of fastening lever 3 is in a plane parallel to a plane defined by what might be called the y-axis and the z-axis. In this case, the x-axis would be coincident with axis of rotation 44. Fastening lever 3 would extend into and out of the page in the z-axis. It will be understood that perpendicular or orthogonal is meant to include roughly or approximately perpendicular or orthogonal such that some variation within between about one to ten degrees may occur.

However, axis of rotation 44 could be angled away from wall 23 e.g., by providing that axis of rotation 44 is at an angle with respect to the z-axis and the x-axis while still perpendicular to the y-axis such as by bending flange 6 inwardly toward the interior of meter box base 19. In this case, axis of rotation 44 may still be perpendicular with respect to an axial direction x. In this case, when fastening lever 3 is rotated, then terminate end engagement surface 40A does not come into contact with wall 23 until near the end of rotation, which occurs when stop surface 41A engages the underside of front flange 21. Thus, in this embodiment, at least one axial direction of axis of rotation 44 is perpendicular to the y-axis and/or wall 23.

As the lever 3 is rotated, the compressible member 30, due to the limited space defined by a lower surface of front flange 21 and wall 23 of the watthour meter box base 19 and the terminate end 40A of the flange 8, will compress. The compression of compressible member 30 ensures a “secure feel” and a tighter fit of the locking bracket to the watthour meter box base. The installer continues to rotate the fastening lever 3 until stop surface 41A engages the inside surface of front flange 21. In a preferred embodiment, the flange 9 of the fastening lever 3 is in a generally parallel position to the flange 10 of the clamping member 2 when stop surface 41A engages the inside surface of front flange 21. The front flange 21 of the meter box base 19 is now trapped between the compression member 30 disposed on flange 8 of the fastening lever 3, and the flange 10 of the clamping member 2. As shown in FIG. 8, when meter box lid 20 is installed onto the meter box base 19, then the upper surface 42 of flange 9 may be prevented from movement and/or may be biasingly engaged with the inner surface of box lid 20. The compression member 30 provides a bias force between locking bracket 1 and wall 23 and front flange 21 and also frictional engagement which acts to hold the locking bracket 1 securely in place for subsequent attachment of lock housing 14.

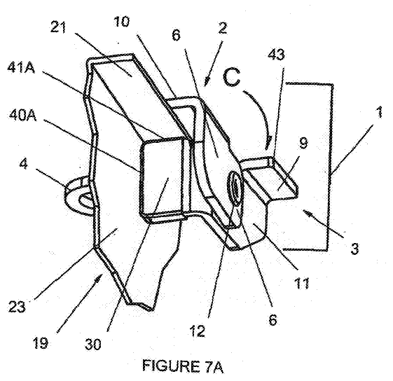

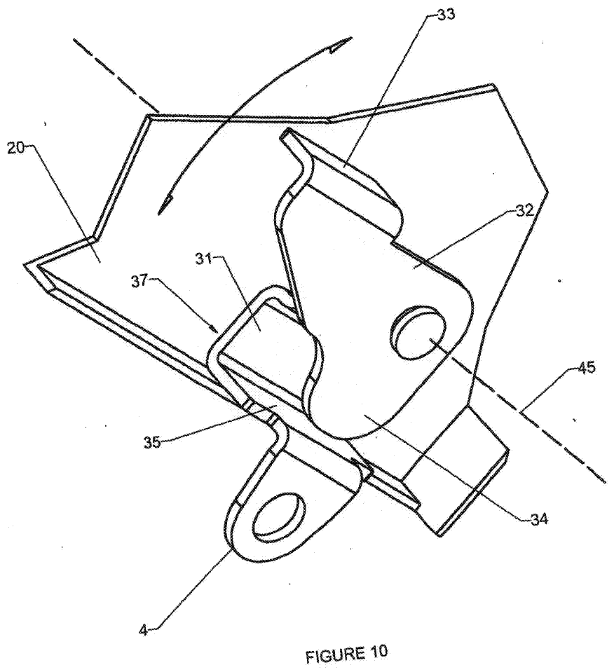

Referring to FIG. 9, the meter box lid 20 is then installed onto the meter box base 19. The meter box lid 20 covers the flange 9 of the fastening lever 3 and the flange 10 of the clamping member 2.

Once the lid 20 is in place, the aperture 22 in the lock housing 14 is aligned with the fastening shelf 4 of the clamping member 2. The lock housing 14 is then slid onto the fastening shelf 4 of the clamping member 2, shown by movement arrow “D” in FIG. 6A. The locking shaft 16 is then inserted through the aperture 17 in the lock housing 14, shown by movement arrow “E” which is perpendicular to the fastening shelf 4. Shown in FIGS. 2, 2A, 4, and 4A, the locking balls 18 of the locking shaft 16 become trapped as they pass though the aperture 7 of the fastening shelf 4; this prevents the removal of the locking shaft 16 from the lock housing 14. Fastening shelf 4 may have tapering sides to permit easier insertion or guiding of fastening shelf 4 into aperture 22 of locking shaft 16. Aperture 22 is preferably sized to mate with the sides of fastening shelf 4 at least near flange 5 so as to prevent sideways movement of clamping member 2.

The perpendicular flange 15 of the lock housing 14 prevents meter box lid 20 removal; consequently the meter box lid 20 prevents the fastening lever 3 from rotating to the “open position”. The fastening lever 3, the clamping member 2, the connector 12, lock housing 14, the lid 20, and the meter box base 19, interact together to prevent the removal of both the meter box lid 20 and the entire locking apparatus.

Referring back to FIGS. 2, 3, 4, 5, 6, 7, and 8 when flexural member 13 is utilized, the compressive biasing force so produced between clamping member 2 and fastening lever 3 results in a biasing being applied against both sides of wall 23 of the meter box base 19. On the inner side of wall 23, the periphery 40 of flange 8 of fastening lever 3 is urged into engagement with wall 23. On the outer surface of wall 23, inner surface of flange 5 of clamping bracket 2 is biased toward engagement with the outer side of wall 23. Fastening lever 3 is rotated until stop surface 41 engages the inner surface of front flange 21. In a preferred embodiment, the flange 9 of the fastening lever 3 is in a generally parallel position to the flange 10 of the clamping member 2 when stop surface 41 engages the inside surface of front flange 21. The front flange 21 of the meter box base 19 is now trapped between the compression member 30 disposed on flange 8 of the fastening lever 3, and the flange 10 of the clamping member 2. As shown in FIG. 8, when meter box lid 20 is installed onto the meter box base 19, then the upper surface 42 of flange 9 may be prevented from movement and/or may be engaged with the inner surface of box lid 20. If it is desired to provide biased engagement of flange 9 with inner surface of box lid 20, then compression member 30 may be utilized and/or flange 9 may be provided with resilient compression material that may be in the form of a cap such as the cap shape of compressible member 30, or resilient compression material can otherwise be applied to flange 9.

In an alternate embodiment, compressible member 30 may or may not be used. In this alternate embodiment, a different compressible member, comprising a different shape, material, or attachment means as shown in the illustrations, may be disposed on the inside of flange 5 of the clamping member 2. In this embodiment, as the fastening lever 3 is rotated to a “closed position” as previously described, the flange 23 of the watthour meter box base 19 becomes trapped between the terminate end of flange 8 disposed on the fastening lever 3, and the compressible member, performing a similar function as previously described.

In another alternate embodiment, one or more compressible members may or may not be used. Assuming a compressible material is not used, in this embodiment, as the fastening lever 3 is rotated to a “closed position” as previously described, the wall 23 of the meter box base 19 becomes trapped between the terminate end 40 of flange 8 disposed on the fastening lever 3, and the flange 5 of the clamping member 2.

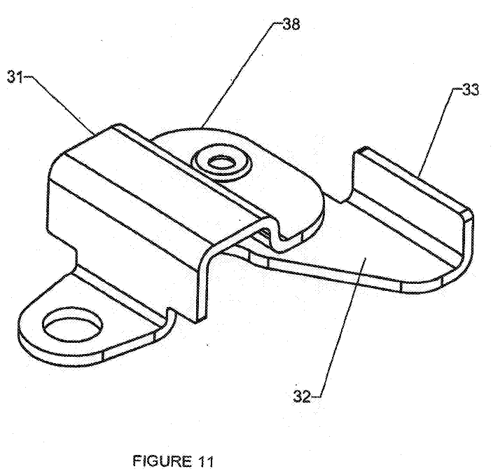

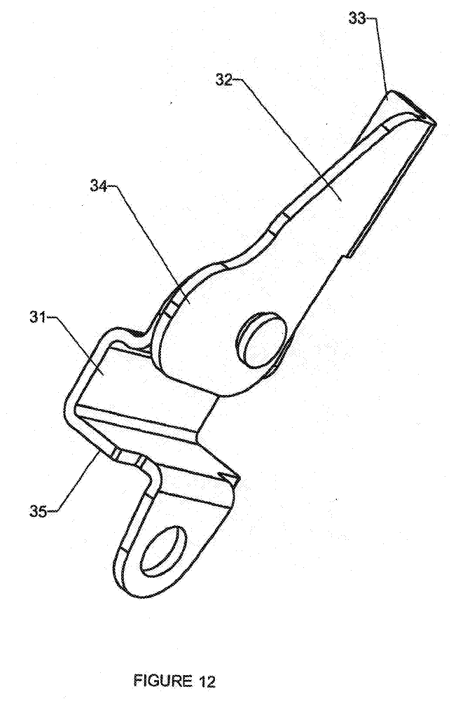

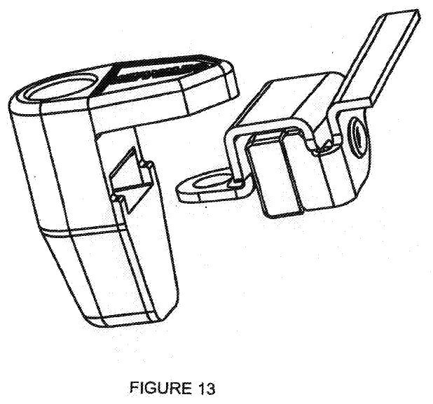

In another alternate embodiment, shown in FIGS. 10-12, a compressible member may not be used. In this embodiment, the lever 32 comprises an engaging lobe 34. The lever 32 rotates in a generally parallel relationship to flange 38 of clamping member 37. Thus, axis of rotation 45 may be generally orthogonal to metal box cover 20, parallel to wall 23, perpendicular to flange 35 which engages an outer surface of wall 23, and parallel to plane of fastening shelf 4. Flange 31 is in a generally perpendicular relationship to flange 35 of the clamping bracket 37. As the fastening lever 32 is rotated to a “closed position” as shown in FIGS. 10,11, the flange 23 of the meter box base 19 becomes trapped between the engaging lobe 34 disposed on the fastening lever 32, and the flange 35 of the clamping member 37.

In another example embodiment of the lever end 9 shown in FIG. 3 is in functional cooperation with a portion 15 of a lock housing mounted to a portion of the clamping member such that the lock prevents rotation of the lever to an open position if the lid is pried upwardly.

In another example embodiment of the apparatus the lever end 9 is in functional cooperation with a portion of a meter box lid 20 such that the lid prevents rotation of the lever to an open position.

In another example embodiment of the apparatus shown in FIGS. 3 and 6 the lever end 9 is at least partially outside the interior of the meter box in a mounting position and at least partially inside the interior of the meter box in a locked position.

In another example embodiment of the apparatus further comprises the meter box.

In another example embodiment of the apparatus further comprises a locking structure (e.g., 14 or other types of locking structures adaptable for use with the invention) for functional cooperation with said clamping member 2 for securing a meter box lid to a meter box base.

Various other example embodiments provide an apparatus that may be adapted for use on a utility service enclosure. Such a utility service enclosure is used not only in the electric utility industry (e.g., a meter box) but also in the gas, water, cable, TV utility industries or in other utility industries.

The design described does not limit the scope of the invention; the number of flanges may change, or various components may be added or removed to the above-described concept to aid in improved security and operation.

The foregoing disclosure and description of the invention is illustrative and explanatory of presently preferred embodiments of the invention and variations thereof, and it will be appreciated by those skilled in the art, that various changes in the design, organization, order of operation, means of operation, equipment structures and location, methodology, the use of mechanical equivalents, such as different types of fasteners and locking devices than as illustrated whereby different steps may be utilized, as well as in the details of the illustrated construction or combinations of features of the various elements may be made without departing from the spirit of the invention. As well, the drawings are intended to describe the concepts of the invention so that the presently preferred embodiments of the invention will be plainly disclosed to one of skill in the art but are not intended to be manufacturing level drawings or renditions of final products and may include simplified conceptual views as desired for easier and quicker understanding or explanation of the invention. As well, the relative size and arrangement of the components may be varied from that shown and the invention still operate well within the spirit of the invention as described hereinbefore and in the appended claims. Thus, various changes and alternatives may be used that are contained within the spirit of the invention.

Accordingly, the foregoing disclosure and description of the invention is illustrative and explanatory thereof, and it will be appreciated by those skilled in the art, that various changes in the ordering of steps, ranges, interferences, spacings, hardware, and/or attributes and parameters, as well as in the details of the illustrations or combinations of features of the methods and system discussed herein, may be made without departing from the spirit of the invention.

1. An apparatus for securing a box cover to a meter box, said meter box being defined by a plurality of side walls, said apparatus comprising:
a clamping member attachable to one of said plurality of side walls;
a fastening lever;
a pivotal connection between said clamping member and said fastening lever, said pivotal connection comprising an axis of rotation extending through said pivotal connection, said axis of rotation extending into at least one of said box cover or said one of said plurality of side walls when said box cover is secured to said meter box.

2. The apparatus of claim 1, further comprising a portion of said fastening lever member adapted to bear against said one of said plurality of side walls of said meter box.

3. The apparatus of claim 2, wherein said portion of said fastening lever member adapted to bear against said one of said plurality of side walls of said meter box comprises a planar surface.

4. The apparatus of claim 3, wherein said planar surface is rotatable with respect to said one of said plurality of side walls.

5. The apparatus of claim 2, wherein said portion of said fastening lever member adapted to bear against said one of said plurality of side walls of said meter box is arcuate.

6. The apparatus of claim 2, further comprising a resilient compression member secured to said portion of said fastening lever member adapted to bear against said one of said plurality of side walls.

7. The apparatus of claim 1, further comprising a biasing member secured to at least one of said clamping member or said fastening lever.

8. The apparatus of claim 1 wherein said clamping member comprises a first planar surface and said fastening lever comprises a second planar surface, said pivotal connection pivotally interconnecting said first planar surface to said second planar surface.

9. The apparatus of claim 1, further comprising a lever end, said lever end surface being pivotally moveable between a mounting and a locked position without entering into an interior of said meter box.

10. The apparatus of claim 1, wherein said lever end is in functional cooperation with a portion of a lock housing mounted to a portion of the clamping member such that said lock prevents rotation of said lever to an open position.

11. The apparatus of claim 1, wherein said lever end is in functional cooperation with a portion of a meter box lid such that said lid prevents rotation of said lever to an open position.

12. The apparatus of claim 1, wherein said lever end being at least partially outside the interior of the meter box in a mounting position and at least partially inside the interior of the meter box in a locked position.

13. (canceled)

14. The apparatus of claim 1, further comprising said a locking structure adapted for functional cooperation with said clamping member for securing a meter box lid to a meter box base.

15. An apparatus for securing a box cover to a meter box, said meter box being defined by a plurality of side walls, said apparatus comprising:
a clamping member attachable to one of said plurality of side walls;
a fastening lever with a planar engagement surface adapted to bear against said one of said plurality of side walls of said meter box; and
a pivotal connection between said clamping member and said fastening lever whereby said planar engagement surface rotates with respect to said one of said plurality of side walls.

16. The apparatus of claim 15, further comprising a compression member secured to said planar engagement surface.

17. The apparatus of claim 15, further comprising a biasing member secured to at least one of said clamping member or said fastening lever.

18. The apparatus of claim 15, further comprising an axis of rotation extending through said pivotal connection, said axis of rotation extending into said one of said plurality of side walls.

19. The apparatus of claim 18, wherein said axis of rotation being at least approximately orthogonal to said one of said plurality of side walls.

20-27. (canceled)

28. A method for manufacturing an apparatus for securing a box cover to a meter box, said meter box being defined by a plurality of side walls, said apparatus comprising:
providing a clamping member attachable to one of said plurality of side walls;
selectively securing a fastening lever to said clamping member in at least one of two different design configurations, said first design configuration requiring that said fastening lever is mounted for rotation in a first rotational direction to fasten said clamping member to said one of said plurality of side walls, and said second design configuration requiring that said fastening lever is mounted for rotation in a second rotational direction to fasten said clamping member to said one of said plurality of side walls.

29. (canceled)
